(19) United States
(12) Patent Application Publication
(10) Pub. No.: US 2025/0386514 A1
(43) Pub. Date: Dec. 18, 2025

(54) METHOD OF MANUFACTURING SEMICONDUCTOR DEVICE

(71) Applicant: SAMSUNG ELECTRONICS CO., LTD., Suwon-si (KR)

(72) Inventor: Jonghyuk Lee, Suwon-si (KR)

(21) Appl. No.: 19/045,101

(22) Filed: Feb. 4, 2025

(30) Foreign Application Priority Data
Jun. 14, 2024 (KR) 10-2024-0077465

(51) Int. Cl. H10B 61/00; H10N 50/01

(52) U.S. Cl. CPC H10B 61/00; H10N 50/01

(57) ABSTRACT

An example method for manufacturing a semiconductor device comprises sequentially forming a lower electrode layer, a magnetic tunnel junction structure layer, a first upper electrode layer, and a first etch stop layer on a substrate. The first etch stop layer is removed in a region and a second upper electrode layer is formed. A second etch stop layer and a sacrificial electrode layer are sequentially formed on the second upper electrode layer. The lower electrode layer, the magnetic tunnel junction structure layer, the first upper electrode layer, the second upper electrode layer, the second etch stop layer, and the sacrificial electrode layer are patterned to form preliminary cell structures. Spacers covering side surfaces of the preliminary cell structures are formed and spaced apart from each other. The sacrificial electrode layer and the second etch stop layer are sequentially removed from each of the preliminary cell structures.

### CROSS-REFERENCE TO RELATED APPLICATION

This application claims benefit of priority to Korean Patent Application No. 10-2024-0077465 filed on Jun. 14, 2024, in the Korean Intellectual Property Office, the disclosure of which is incorporated herein by reference in its entirety.

### BACKGROUND

A magnetoresistive memory device is a nonvolatile memory device that reads and writes data using a magnetic tunnel junction layer that includes two magnetic layers and a tunnel barrier layer interposed therebetween. A resistance value of the magnetic tunnel junction layer may vary, depending on a magnetization direction of the two magnetic layers, and the data may be programmed or erased using a difference in this resistance value.

### SUMMARY

The present disclosure relates to a method for manufacturing a semiconductor device with improved electrical characteristics.

In general, according to some aspects, a method for manufacturing a semiconductor device may comprise: forming an interlayer insulating layer and an interconnection structure penetrating at least a portion of the interlayer insulating layer on a substrate including a first region on which memory cells are arranged and a second region on which a peripheral circuit is arranged; sequentially forming a lower electrode layer, a magnetic tunnel junction structure layer, a first upper electrode layer, and a first etch stop layer on the interlayer insulating layer and the interconnection structure; removing the first etch stop layer on the first region, and forming a second upper electrode layer on the first and second regions; sequentially forming a second etch stop layer and a sacrificial electrode layer on the first and second regions; forming a mask pattern on the first region, and patterning the first upper electrode layer, the second upper electrode layer, the second etch stop layer, and the sacrificial electrode layer with the mask pattern; performing an ion beam etch process to pattern the lower electrode layer and the magnetic tunnel junction structure layer on the first region, and forming preliminary cell structures, each of which includes the lower electrode layer, the magnetic tunnel junction structure layer, the first upper electrode layer, the second upper electrode layer, the second etch stop layer, and the sacrificial electrode layer, which are sequentially stacked; forming a spacer layer covering an upper surface and side surfaces of each of the preliminary cell structures; removing a portion of the spacer layer to form spacers covering the respective side surfaces of the preliminary cell structures and spaced apart from each other between the preliminary cell structures; removing the sacrificial electrode layer from each of the preliminary cell structures to expose the second etch stop layer; removing the second etch stop layer from each of the preliminary cell structures to expose the second upper electrode layer; and forming a bit line connected to each of the second upper electrode layers.

In general, according to some aspects, a method of manufacturing a semiconductor device may comprises: sequentially forming a lower electrode layer, a magnetic tunnel junction structure layer, a first upper electrode layer, and a first etch stop layer on a substrate; removing the first etch stop layer in a region and forming a second upper electrode layer; sequentially forming a second etch stop layer and a sacrificial electrode layer on the second upper electrode layer; patterning the lower electrode layer, the magnetic tunnel junction structure layer, the first upper electrode layer, the second upper electrode layer, the second etch stop layer, and the sacrificial electrode layer to form preliminary cell structures spaced apart from each other; forming spacers covering side surfaces of the preliminary cell structures and spaced apart from each other between the apart preliminary cell structures; and sequentially removing the sacrificial electrode layer and the second etch stop layer from each of the preliminary cell structures.

In general, according to some aspects, a method of manufacturing a semiconductor device may comprise: sequentially forming a lower electrode layer, a magnetic tunnel junction structure layer, and a first upper electrode layer on a substrate; sequentially forming a second upper electrode layer, an etch stop layer, and a sacrificial electrode layer on the first upper electrode layer; patterning the lower electrode layer, the magnetic tunnel junction structure layer, the first upper electrode layer, the second upper electrode layer, the etch stop layer, and the sacrificial electrode layer to form preliminary cell structures spaced apart from each other; forming spacers covering side surfaces of the preliminary cell structures and spaced apart from each other between the preliminary cell structures; and removing the sacrificial electrode layer and the etch stop layer from each of the preliminary cell structures, wherein upper ends of the spacers are positioned on a level higher than an upper surface of the second upper electrode layer and lower ends of the spacers are positioned on a level lower than a lower surface of the lower electrode layer.

In general, according to some aspects, a semiconductor device may comprise: a substrate; an interlayer insulating layer on the substrate; lower contact plugs penetrating a portion of the interlayer insulating layer; cell structures on the lower contact plugs and respectively comprising a lower electrode layer, a magnetic tunnel junction structure layer, a first upper electrode layer, and a second upper electrode layer, which are sequentially stacked; spacers covering side surfaces of the cell structures and exposing the interlayer insulating layer between the cell structures; and bit lines on the cell structures, wherein an upper end of each of the spacers is on a level higher than an upper surface of the second upper electrode layer, and a lower end of each of the spacers is on a level lower than a lower surface of the lower electrode layer.

In general, according to some aspects, in the semiconductor device, each of the plurality of spacers has a protrusion protruding onto the second upper electrode layer.

In general, according to some aspects, in the semiconductor device, a height of the protrusion ranges from 50 Å to 100 Å.

In general, according to some aspects, in the semiconductor device, the lower end of each of the plurality of spacers contacts the interlayer insulating layer.

In general, according to some aspects, in the semiconductor device, the lower end of each of the plurality of spacers are spaced apart from the plurality of lower contact plugs in a horizontal direction.

### BRIEF DESCRIPTION OF THE DRAWINGS

The above and other aspects, features, and advantages of the present disclosure will be more clearly understood from the following detailed description, taken in conjunction with the accompanying drawings.

FIG. 1A is a schematic plan view of an example of a semiconductor device, and FIG. 1B is a diagram illustrating an example of a memory cell of a magnetoresistive memory device.

FIG. 2 is a schematic cross-sectional view of an example of a semiconductor device.

FIG. 3 is a schematic partially enlarged view of an example of a semiconductor device.

FIGS. 4A to 4C are schematic enlarged views of a portion of an example of a semiconductor device.

FIG. 5 is a schematic cross-sectional view of an example of a semiconductor device.

FIG. 6 is a flowchart illustrating an example of a method of manufacturing a semiconductor device.

FIGS. 7A to 7J are schematic cross-sectional views illustrating an example of a method of manufacturing a magnetoresistive memory device.

### DETAILED DESCRIPTION

Hereinafter, example implementations of the present disclosure will be described with reference to the accompanying drawings.

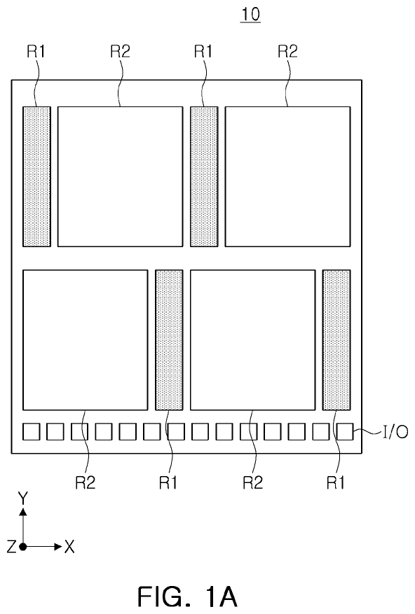

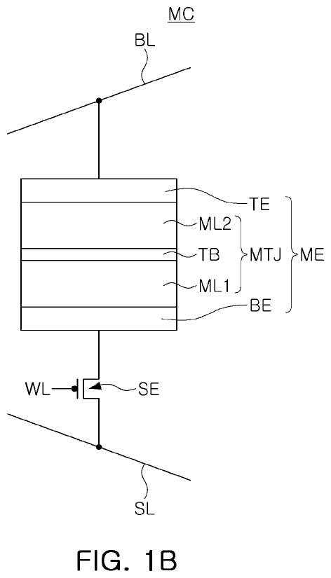

FIG. 1A is a schematic plan view of an example of a semiconductor device, and FIG. 1B is a diagram illustrating an example of a memory cell of a magnetoresistive memory device.

Referring to FIG. 1A, a semiconductor device 10 may include first regions R1 in which magnetoresistive random access memory (MRAM) elements are arranged, second regions R2 in which logic devices are arranged, and input/output pads I/O. The semiconductor device 10 may be a system, such as a System on Chip (SoC) or a Micro Control Unit (MCU), and may include an embedded MRAM. However, in some implementations, the semiconductor device 10 may not include the second region R2 and may be an MRAM device.

The first region R1 may include a cell region in which memory cells are arranged two- or three-dimensionally and a circuit region for operating the memory cells. The second region R2 may be a region in which logic circuits are arranged. The second regions R2 may be arranged on at least one side of the first regions R1. The number, size, and relative arrangement of the first regions R1 and the second regions R2 may vary depending on implementations.

The input/output pads I/O may be arranged on at least one side of the first regions R1 and the second regions R2, and may be arranged in a row along at least one edge of the semiconductor device 10, for example. Alternatively, the input/output pads I/O may be arranged in a row in a region between the first regions R1 and the second regions R2. The input/output pads I/O may be configured to transmit and receive electrical signals to and from an external device, etc. The input/output pads I/O may be a region connected to an input/output circuit of circuits in the semiconductor device 10, for example.

Referring to FIG. 1B, each memory cell MC may include a memory element ME and a selection element SE. The memory element ME and the selection element SE may be electrically connected to each other in series. The memory element ME may be connected between a bit line BL and the selection element SE. The selection element SE may be connected between the memory element ME and a source line SL, and may be controlled by a word line WL

The memory element ME may include a magnetic tunnel junction structure layer MTJ, a lower electrode layer BE, and an upper electrode layer TE. The magnetic tunnel junction structure layer MTJ may be a variable resistance element which may be switched between two resistance states by an electrical pulse applied thereto. The magnetic tunnel junction structure layer MTJ may include at least one ferromagnetic material and/or at least one antiferromagnetic material. Specifically, the magnetic tunnel junction structure layer MTJ may include a first magnetic layer ML1, a second magnetic layer ML2, and a tunnel barrier layer TB therebetween.

Each of the first and second magnetic layers ML1 and ML2 may include at least one magnetic layer made of a magnetic material. One of the first and second magnetic layers ML1 and ML2 may be a fixed layer having a magnetization direction fixed in one direction regardless of an external magnetic field under a typical use environment. The other of the first and second magnetic layers ML1 and ML2 may be a free layer whose magnetization direction is changed between two stable magnetization directions by an external magnetic field. An electrical resistance of the magnetic tunnel junction structure layer MTJ may be much greater when the magnetization directions of the fixed layer and the free layer are antiparallel to each other than when they are parallel to each other. The electrical resistance of the magnetic tunnel junction structure layer MTJ may be adjusted by changing the magnetization direction of the free layer. Accordingly, the memory element ME may store data in the memory cell MC by utilizing a difference in the electrical resistance depending on the magnetization directions of the fixed layer and the free layer.

The lower electrode layer BE may be interposed between the first magnetic layer ML1 and the selection element SE, and the upper electrode layer TE may be interposed between the second magnetic layer ML2 and the bit line BL.

The selection element SE may be configured to selectively control a flow of a charge passing through the memory element ME. For example, the selection element SE may be a field effect transistor. In some implementations, the selection element SE may be a fin field effect transistor (FinFET) or a multi-bridge channel field effect transistor (MBCFET™).

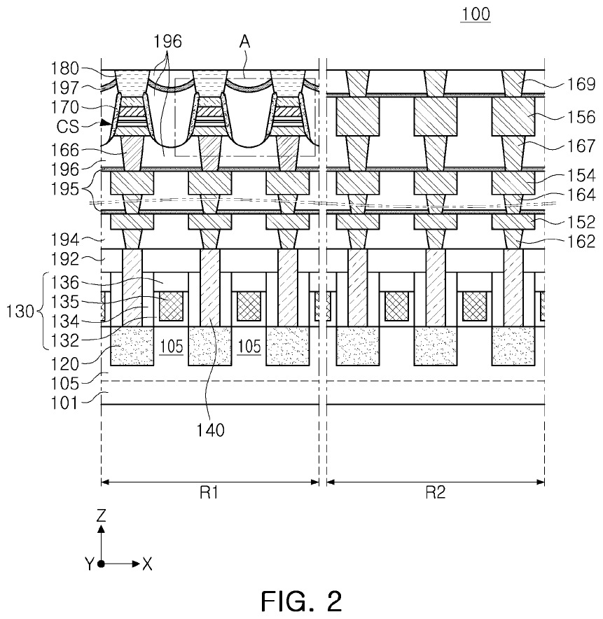

FIG. 2 is a schematic cross-sectional view of an example of a semiconductor device.

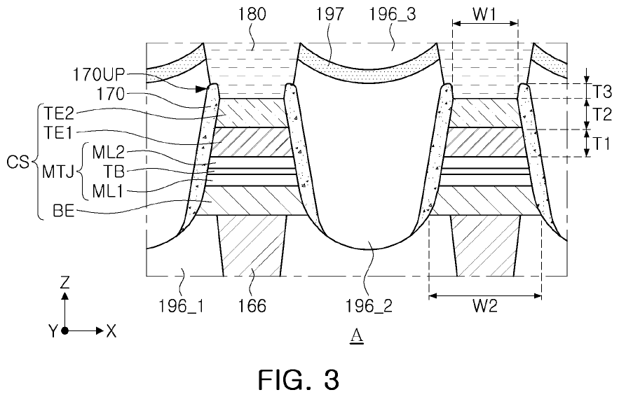

FIG. 3 is a schematic enlarged view of a portion of an example of a semiconductor device. FIG. 3 illustrates enlarged ‘A’ region of FIG. 2.

Referring to FIGS. 2 and 3, the semiconductor device 100 may include a first region R1 and a second region R2. The semiconductor device 100 may include a substrate 101, an active region 105 on the substrate 101, gate structures 130 on the active region 105, source/drain regions 120 at both sides of the gate structures 130, lower contact plugs 140 connected to the source/drain regions 120, first and second contact plugs 162 and 164 on the lower contact plugs 140, first and second interconnection lines 152 and 154 respectively connected to the first and second contact plugs 162 and 164, first to third interlayer insulating layers 192, 194 and 196, and first and second barrier layers 195 and 197.

The semiconductor device 100 may further include upper contact plugs 166, cell structures CS on the upper contact plugs 166, spacers 170 on sidewalls of the cell structures CS, and bit lines 180 connected to the cell structures CS, in the first region R1. The semiconductor device 100 may further include third and fourth contact plugs 167 and 169 and third interconnection lines 156 connected thereto, in the second region R2.

The semiconductor device 100 may include the first region R1 and the second region R2, as described above with reference to FIG. 1A. In the first region R1, the cell structure CS corresponding to the memory element ME of FIG. 1B may be arranged, and in the second region R2, elements forming a logic circuit, such as FinFETs, may be arranged. However, depending on description manner, the first region R1 and the second region R2 may be described as regions of the substrate 101 rather than regions of the semiconductor device 100.

The substrate 101 may have an upper surface extending in an X-direction and a Y-direction. The substrate 101 may include a semiconductor material, such as a group IV semiconductor, a group III-V compound semiconductor or a group II-VI compound semiconductor. For example, the group IV semiconductor may include silicon, germanium or silicon-germanium. The substrate 101 may be provided as a bulk wafer, an epitaxial layer, a silicon on insulator (SOI) layer, or a semiconductor on insulator (SeOI) layer.

The active region 105 is defined by a shallow trench isolation (STI) structure, and may be arranged to extend in a first direction, for example, the X-direction. Depending on description manners, it may also be possible to describe the active region 105 as a portion of the substrate 101. The active region 105 may be formed as a portion of the substrate 101, or may include an epitaxial layer grown from the substrate 101. However, at both sides of the gate structures 130, the active regions 105 may be partially recessed to form recessed regions, and the source/drain regions 120 may be arranged in the recessed regions.

The gate structures 130 may extend in one direction, for example, the Y-direction, on the substrate 101. Each of the gate structures 130 may include a gate dielectric layer 132, gate spacers 134, a gate electrode layer 135, and a gate capping layer 136.

The gate dielectric layer 132 may include an insulating material, such as silicon oxide or a high-K material. The gate electrode layer 135 may be arranged on the gate dielectric layer 132, and may form, for example, a gate of the selection element SE of FIG. 1B. The gate electrode layer 135 may include a conductive material, and may include a metal, a metal nitride, or doped polysilicon.

The gate spacers 134 may be arranged to cover side surfaces of the gate dielectric layer 132 and the gate capping layer 136. The gate capping layer 136 may be arranged on the gate electrode layer 135. The gate spacers 134 and the gate capping layer 136 may include an insulating material, such as silicon oxide, silicon nitride, or silicon oxynitride.

The source/drain regions 120 may be arranged at both sides of the gate electrode layers 135, respectively, on the active regions 105. The source/drain regions 120 may be arranged in the recessed regions formed by partially recessing an upper portion of the active regions 105. Upper surfaces of the source/drain regions 120 may be positioned at a height equal to or higher than lower surfaces of the gate structures 130, and the height may vary depending on implementations.

The first to third interlayer insulating layers 192, 194 and 196 may be sequentially stacked on the gate structures 130. The first interlayer insulating layer 192 may cover the gate structures 130, the second interlayer insulating layer 194 may cover side surfaces of the first and second contact plugs 162 and 164 and the first and second interconnection lines 152 and 154, and the third interlayer insulating layer 196 may be arranged on the second interconnection lines 154. The first to third interlayer insulating layers 192, 194 and 196 may include at least one of an oxide, a nitride, or an oxynitride, and may include, for example, a low-K material. The third interlayer insulating layer 196 may include a lower layer 196_1, an intermediate layer 196_2 and an upper layer 196_3 which are sequentially stacked, as illustrated in FIG. 3. Depending on implementations, each of the first and second interlayer insulating layers 192 and 194 may also include a plurality of insulating layers.

The first barrier layers 195 may be arranged on upper surfaces of the first and second interconnection lines 152 and 154. The second barrier layer 197 may be arranged within the third interlayer insulating layer 196 on the cell structures CS in the first region R1 and on upper surfaces of the third interconnection lines 156 in the second region R2. Relative levels of the second barrier layer 197 in the first region R1 and the second region R2 are not limited to those illustrated in FIG. 2. The first and second barrier layers 195 and 197 may include an insulating material such as SiCN.

The lower contact plugs 140 may be arranged to connect the source/drain regions 120 and the first contact plugs 162 at both sides of the gate structures 130, respectively. The lower contact plugs 140 may be arranged to penetrate the first interlayer insulating layer 192.

The first and second contact plugs 162 and 164 and the first and second interconnection lines 152 and 154 may form an interconnection structure between the lower contact plugs 140 and the upper contact plugs 166 and between the lower contact plugs 140 and the third contact plugs 167. In example implementations, the numbers of layers of the contact plugs and the interconnection lines forming the interconnection structure and arranged along a Z-direction may vary. The upper contact plugs 166 may be arranged on the interconnection structure in the first region R1. The third and fourth contact plugs 167 and 169 and the third interconnection lines 156 may be arranged on the interconnection structure in the second region R2.

The first contact plugs 162 may vertically connect the lower contact plugs 140 and the first interconnection lines 152. The first interconnection lines 152 may be connected to the first contact plugs 162, and may form, for example, the source line SL of FIG. 1B in the first region R1. The second contact plugs 164 may be arranged on the first interconnection lines 152 to connect the first interconnection lines 152 and the second interconnection lines 154. The second interconnection lines 154 may be arranged on the second contact plugs 164, and may be connected to the upper contact plugs 166 and the third contact plugs 167. In the first region R1, the upper contact plugs 166 may connect the second interconnection lines 154 and the cell structures CS. The upper contact plugs 166 may also be referred to as lower electrode plugs electrically connected to the lower electrode layer BE. In the second region R2, the third contact plugs 167 may be arranged on the same level as the upper contact plugs 166 or on a level overlapping the upper contact plugs 166. In the second region R2, the third interconnection lines 156 may be vertically connected to the third contact plugs 167 and the fourth contact plugs 169. The third interconnection lines 156 may be arranged at the same level as the cell structures CS or at a level overlapping the cell structures CS. The fourth contact plugs 169 may be arranged on the same level as the bit lines 180 or on a level overlapping the bit lines 180.

The first to fourth contact plugs 162, 164, 167 and 169, the upper contact plugs 166 and the first to third interconnection lines 152, 154 and 156 may include a conductive material, for example, at least one of doped silicon, tungsten (W), aluminum (Al), titanium (Ti), tantalum (Ta), titanium nitride (TiN), tantalum nitride (TaN), tungsten nitride (WN), or metal silicide.

Each of the cell structures CS may include a lower electrode layer BE and first and second upper electrode layers TE1 and TE2, and may further include a magnetic tunnel junction structure layer MTJ arranged between the lower electrode layer BE and the first upper electrode layer TE1. The cell structures CS may be structures corresponding to the memory element ME described above with reference to FIG. 1B. In the present implementation, the cell structures CS may have a shape in which a width thereof increases toward the substrate 101. A width W1 of an upper surface of the cell structures CS may be less than a width W2 of a lower surface thereof.

The lower electrode layer BE and the first and second upper electrode layers TE1 and TE2 may include a conductive material, for example, at least one of titanium (Ti), tantalum (Ta), ruthenium (Ru), titanium nitride (TiN), tantalum nitride (TaN), or tungsten (W).

Each of the magnetic tunnel junction structure layers MTJ may include a first magnetic layer ML1, a tunnel barrier layer TB, and a second magnetic layer ML2. For example, the first magnetic layer ML1 may be a fixed layer having a fixed magnetization direction, and the second magnetic layer ML2 may be a free layer whose magnetization direction is freely changed by an external magnetic field. The first and second magnetic layers ML1 and ML2 may have a magnetization direction which is parallel or perpendicular to the upper surface of the substrate 101. The second magnetic layer ML2 may have a magnetization direction that can be changed to a direction parallel or antiparallel to the first magnetic layer ML1.

The first and second magnetic layers ML1 and ML2 may include a magnetic material including a transition metal. The first and second magnetic layers ML1 and ML2 may include, for example, at least one of cobalt (Co), iron (Fe), or nickel (Ni), and may further include other elements, such as boron (B), chromium (Cr), platinum (Pt), palladium (Pd), etc. The first and second magnetic layers ML1 and ML2 may include, for example, at least one of cobalt iron boron (CoFeB), cobalt iron (CoFe), nickel iron (NiFe), cobalt iron platinum (CoFePt), cobalt iron palladium (CoFePd), cobalt iron chromium (CoFeCr), cobalt iron terbium (CoFeTb), cobalt iron gadolinium (CoFeGd), cobalt iron nickel (CoFeNi), cobalt iron (CoFe), or nickel iron (NiFe). In some implementations, each of the first and second magnetic layers ML1 and ML2 may be formed of a plurality of layers.

The tunnel barrier layer TB may be interposed between the first and second magnetic layers ML1 and ML2, and a quantum tunneling phenomenon may occur in the tunnel barrier layer TB. The tunnel barrier layer TB may include an insulating metal oxide. For example, the tunnel barrier layer TB may include magnesium oxide (MgO), aluminum oxide (AlO), or a combination thereof.

In some implementations, a seed layer for a growth of the magnetic tunnel junction structure layer MTJ may be further arranged between the lower electrode layer BE and the magnetic tunnel junction structure layer MTJ. The seed layer may include, for example, at least one of tantalum (Ta), ruthenium (Ru), or an alloy thereof. In some implementations, at least one of a metal oxide layer for improving magnetic properties or a capping layer for protecting the magnetic tunnel junction structure layer MTJ may be further arranged between the magnetic tunnel junction structure layer MTJ and the first upper electrode layer TE1. The metal oxide layer may include, for example, at least one of tantalum oxide (TaO), ruthenium oxide (RuO), magnesium oxide (MgO), zirconium oxide (ZrO), titanium oxide (TiO), vanadium oxide (VO), yttrium oxide (YO), scandium oxide (ScO), or molybdenum oxide (MoO). The capping layer may include, for example, a metal material, a metal oxide, or a magnetic material.

The spacers 170 may be arranged on respective side surfaces of the cell structures CS. The spacers 170 may cover entire side surfaces of the lower electrode layer BE, the magnetic tunnel junction structure layer MTJ, and the first and second upper electrode layers TE1 and TE2. Lower ends of the spacers 170 may be positioned on the lower layer 196_1 of the third interlayer insulating layer 196, and may be in contact with the lower layer 196_1. The lower ends of the spacers 170 may be positioned on a level lower than a lower surface of the lower electrode layer BE, and may be horizontally spaced from the upper contact plugs 166. Upper ends of the spacers 170 may be positioned on a level higher than an upper surface of the second upper electrode layer TE2. The spacers 170 may each include a protrusion 170UP protruding from the upper surface of the second upper electrode layer TE2. An upper end and an inner surface of the protrusion 170UP may be in contact with the bit line 180.

A protrusion length or thickness T3 of the protrusion 170UP may be less than a first thickness T1 of the first upper electrode layer TE1 and a second thickness T2 of the second upper electrode layer TE2. The thickness T3 may, for example, range from about 50 Å to about 100 Å. In some implementations, a specific shape of the protrusion 170UP may vary. The spacers 170 may include an insulating material, such as at least one of an oxide, a nitride, or an oxynitride. The bit lines 180 may be arranged to be in contact with the second upper electrode layers TE2. The bit lines 180 may extend in one direction, such as the Y-direction. Each of the bit lines 180 may have a profile along the protrusion 170UP of the spacer 170 from a lower portion thereof, and may be in contact with an upper end and an inner surface of the protrusion 170UP. In the present implementation, the bit lines 180 may have a profile in which the bit lines 180 is bent and has a decreasing width along an upper end of the spacer 170 or the upper end of the protrusion 170UP. The bit lines 180 may have a less width on the lower surface in contact with the second upper electrode layer TE2 than a width above the spacer 170.

The bit lines 180 may be made of a metal having a low resistivity, and may include, for example, copper (Cu), or tungsten (W). Each of the bit lines 180 may further include a barrier layer.

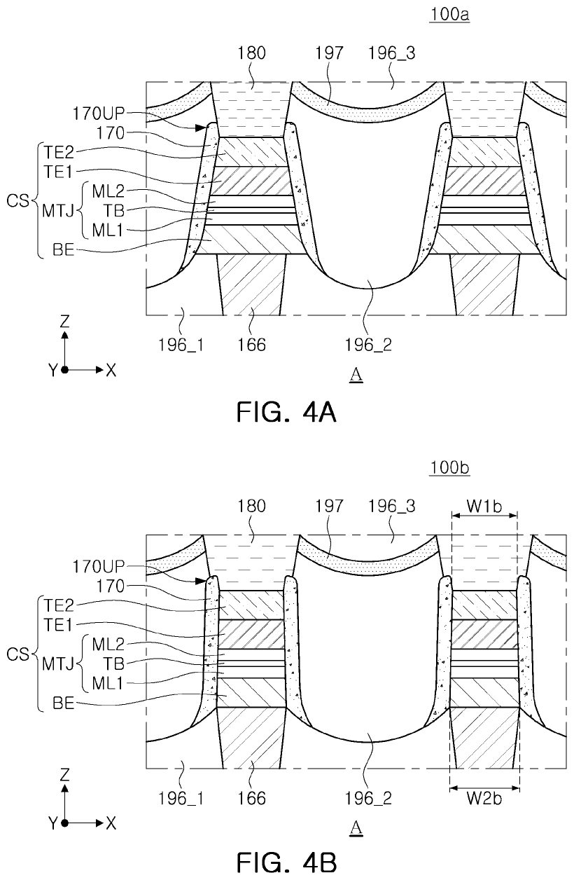

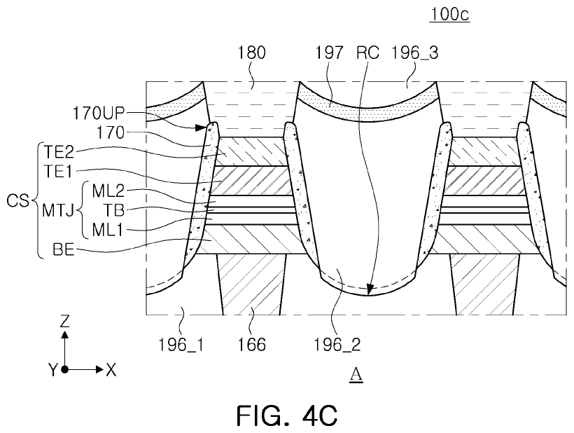

FIGS. 4A to 4C are schematic enlarged views of portions of an example of a semiconductor device. FIGS. 4A to 4C each illustrate an area corresponding to FIG. 3.

Referring to FIG. 4A, in a semiconductor device 100a, the bit lines 180 may have a shape in which a width thereof is uniformly decreased toward the cell structure CS. For example, each of the bit lines 180 may be arranged inside the protrusions 170UP without being in contact with an upper surface of an upper end of the spacer 170.

As such, in example implementations, the relative arrangement relationship between the bit lines 180 and the protrusions 170UP may vary. For example, in some implementations, the bit lines 180 may extend outwardly from the spacers 170 on the spacers 170 to have a width greater than a width between outer surfaces of the spacers 170.

Referring to FIG. 4B, in a semiconductor device 100b, the cell structures CS may have a substantially constant width. A width W1b of an upper surface of the cell structures CS may be equal or similar to a width W2b of a lower surface thereof. In some implementations, the width W1b of the upper surface of the cell structures CS may be greater than the width W2b of the lower surface thereof. In some implementations, a slope of the side surfaces of the cell structures CS may not be constant. For example, in some implementations, a first slope of side surfaces of the first and second upper electrode layers TE1 and TE2 and a second slope of side surfaces of the magnetic tunnel junction structure layer MTJ and the lower electrode layer BE may be different from each other.

Referring to FIG. 4C, in a semiconductor device 100c, the lower layer 196_1 of the third interlayer insulating layer 196 may have an additional recessed region RC between the cell structures CS. The lower layer 196_1 of the third interlayer insulating layer 196 may have a shape in which a portion of the spacers 170 are removed between the cell structures CS.

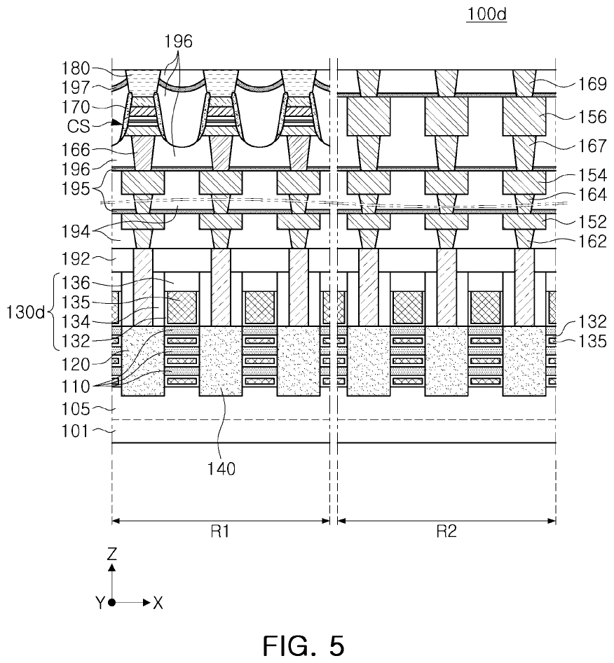

FIG. 5 is a schematic cross-sectional view of an example of a semiconductor device.

Referring to FIG. 5, a semiconductor device 100d may further include channel layers 110. The gate electrode layers 135 may be arranged between the active region 105 and the lowermost channel layer 110, between the channel layers 110, and on the uppermost channel layer 110. Accordingly, the semiconductor device 100d may include MBCFETs, which are gate-all-around type field effect transistors.

The channel layers 110 may include two or more channel layers spaced apart from each other in a vertical direction, such as the Z-direction, on the active region 105. The channel layers 110 may be connected to the source/drain regions 120. The channel layers 110 may have a width equal or similar to a width of the gate structures 130d in the X-direction. The channel layers 110 may be made of a semiconductor material, and may include, for example, at least one of silicon (Si), silicon germanium (SiGe), or germanium (Ge). The number and shape of the channel layers 110 may vary in implementations.

The gate electrode layers 135 may be arranged to fill gaps between the channel layers 110 and extend onto the channel layers 110. The gate electrode layers 135 may be spaced apart from the channel layers 110 by the gate dielectric layers 132.

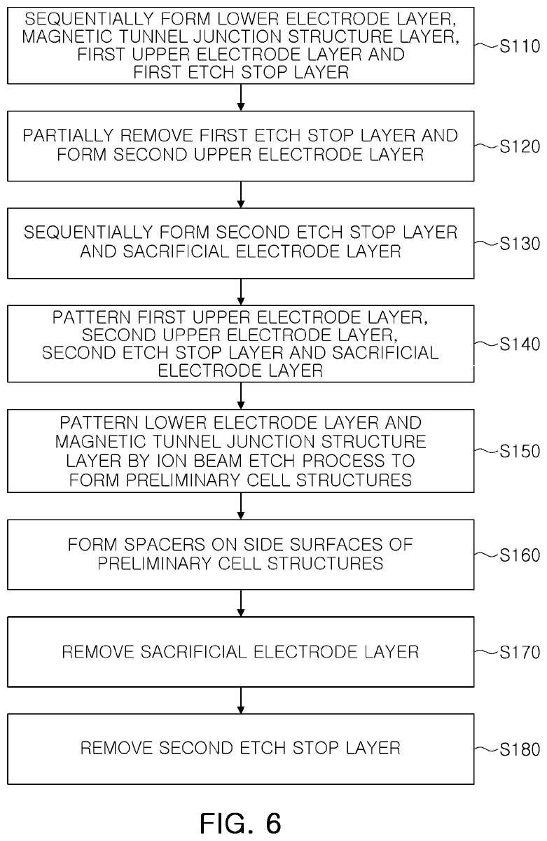

FIG. 6 is a flowchart illustrating an example of a method for manufacturing a semiconductor device.

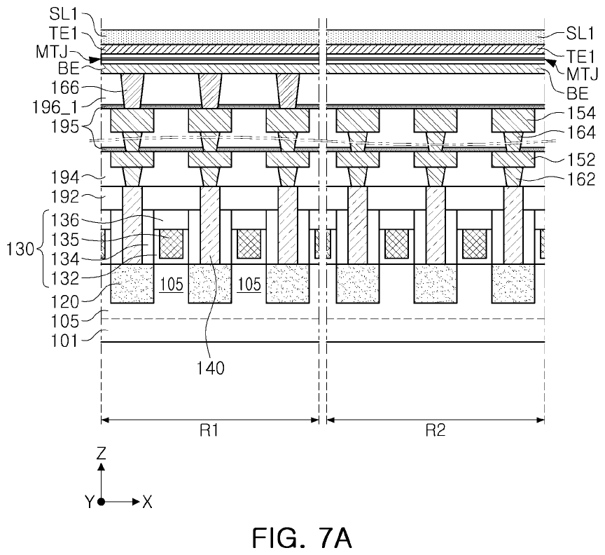

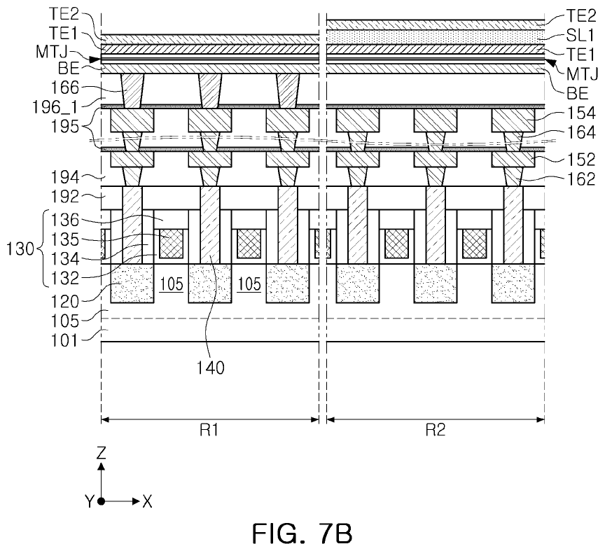

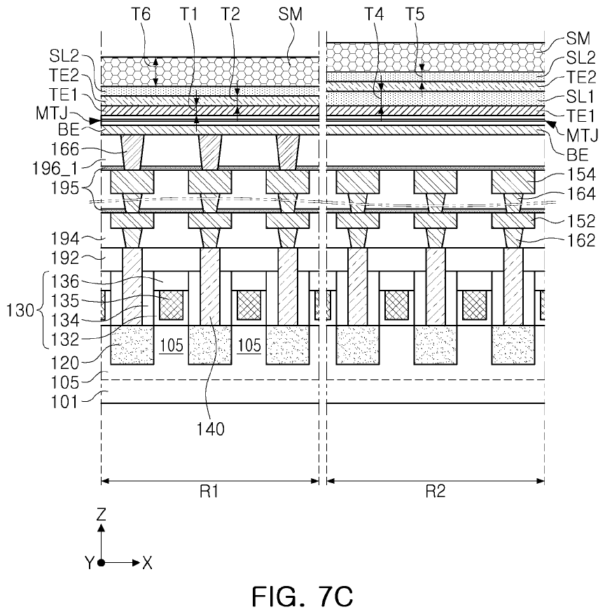

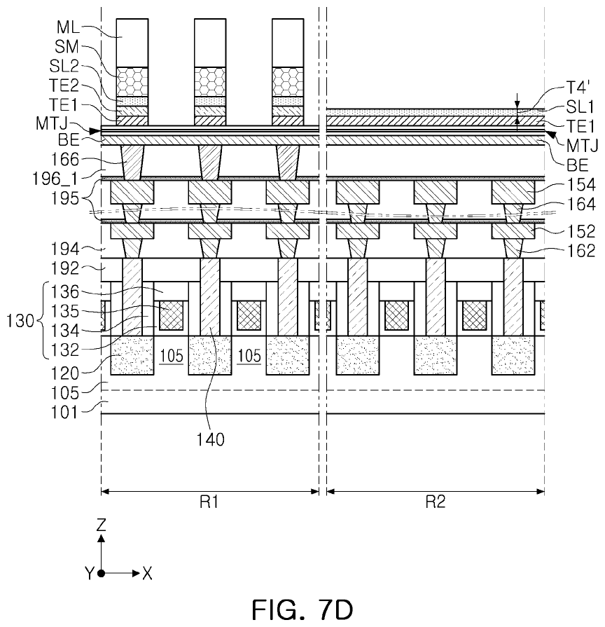

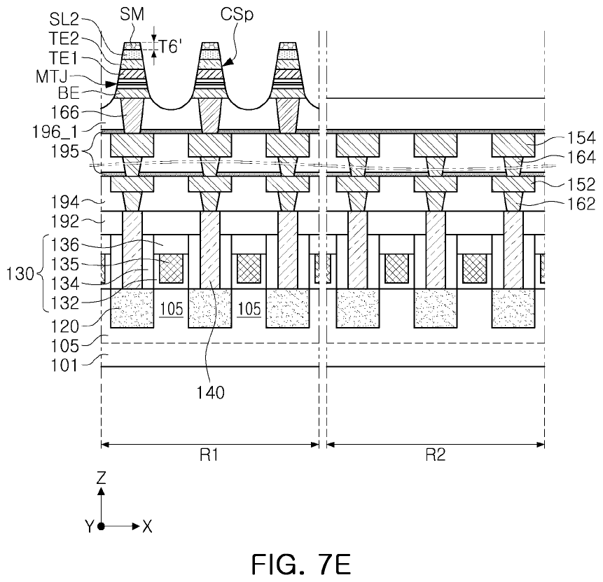

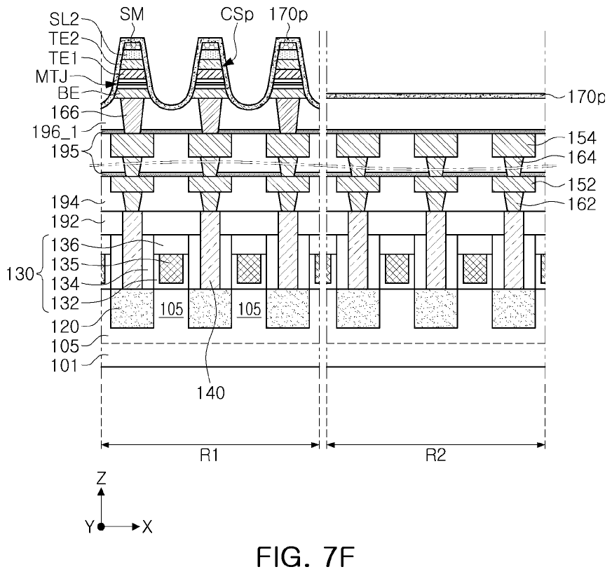

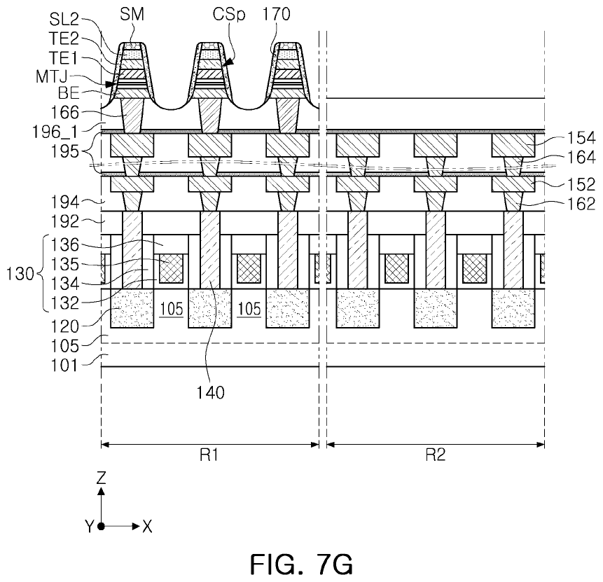

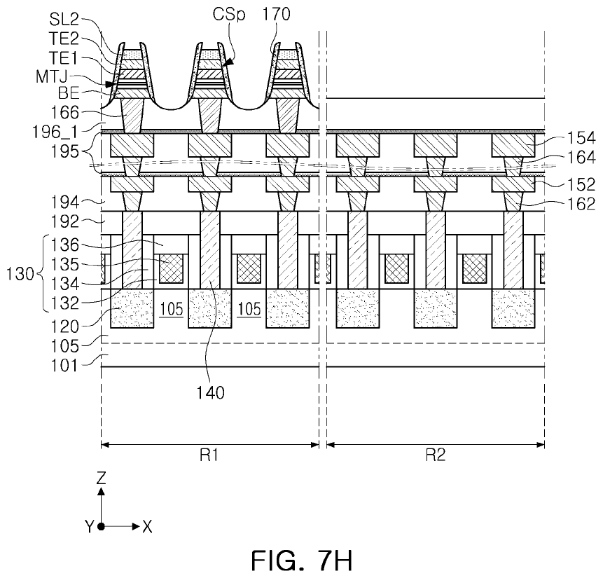

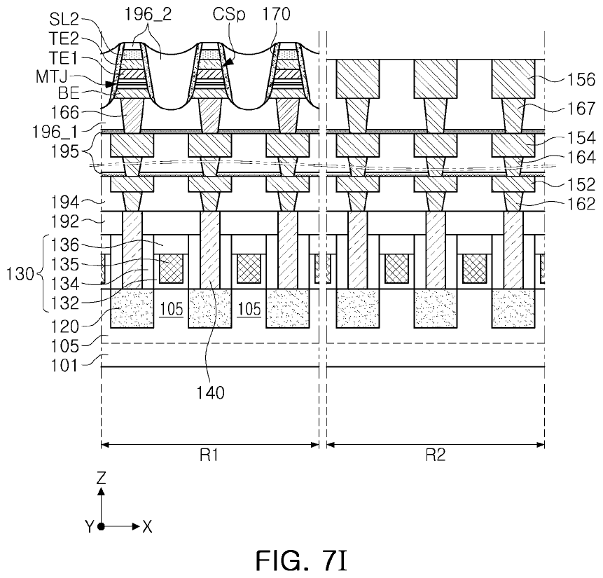

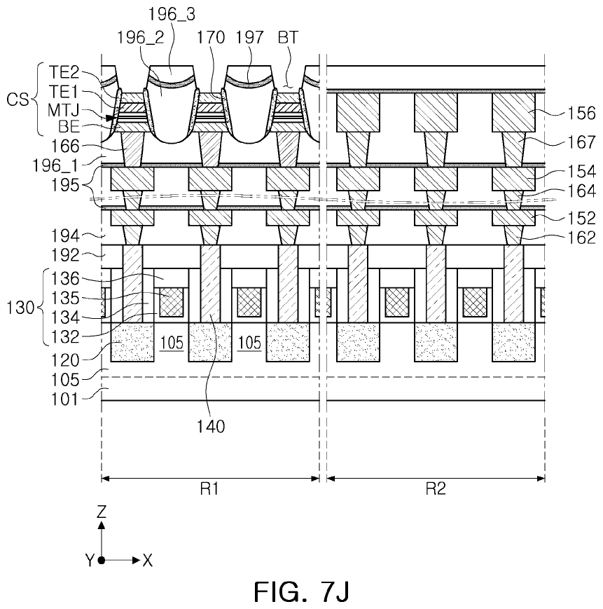

FIGS. 7A to 7J are schematic cross-sectional views illustrating an example of a method for manufacturing a magnetoresistive memory device. FIGS. 7A to 7J each illustrate an area corresponding to FIG. 2.

Referring to FIG. 6 and FIG. 7A, a lower electrode layer BE, a magnetic tunnel junction structure layer MTJ, a first upper metal layer TE1, and a first etch stop layer SL1 may be formed on a substrate 101 (S110).

First, element isolation layers may be formed in the substrate 101 to define an active region 105, gate structures 130 and source/drain regions 120 may be formed on the active region 105, and a first interlayer insulating layer 192 and lower contact plugs 140 may be formed. Next, a second interlayer insulating layer 194 may be formed, first and second contact plugs 162 and 164 and first, second interconnection lines 152 and 154, and first barrier layers 195 may be formed, a lower layer 196_1 of a third interlayer insulating layer 196 may be formed, and then upper contact plugs 166 penetrating the lower layer 196_1 may be formed in the first region R1.

Next, the lower electrode layer BE, the magnetic tunnel junction structure layer MTJ, the first upper metal layer TE1, and the first etch stop layer SL1 may be sequentially formed on the lower layer 196_1 of the third interlayer insulating layer 196. The first etch stop layer SL1 may include, for example, at least one of SiO, SiN, SiCN, SiOC, SiON, or SiOCN.

Referring to FIGS. 6 and 7B, the first etch stop layer SL1 may be partially removed, and a second upper electrode layer TE2 may be formed (S120).

After forming a mask layer opening the first region R1, the first etch stop layer SL1 may be removed from the first region R1. Next, the second upper electrode layer TE2 may be formed over both of the first region R1 and the second region R2. The second upper electrode layer TE2 may be formed on the first upper electrode layer TE1 in the first region R1 and on the first etch stop layer SL1 in the second region R2.

Referring to FIGS. 6 and 7C, a second etch stop layer SL2 and a sacrificial electrode layer SM may be sequentially formed (S130).

The second etch stop layer SL2 and the sacrificial electrode layer SM may be formed on the second upper electrode layer TE2 in both the first and second regions R1 and R2. The second etch stop layer SL2 may include, for example, at least one of SiO, SiN, SiCN, SiOC, SiON, or SiOCN. For example, the second etch stop layer SL2 may include the same material as the first etch stop layer SL1, but is not limited thereto. A thickness T5 of the second etch stop layer SL2 may be less than a thickness T4 of the first etch stop layer SL1, but is not limited thereto.

The sacrificial electrode layer SM may be a layer removed through subsequent processes. The sacrificial electrode layer SM may include the same or different material as the first and second upper electrode layers TE1 and TE2. For example, the sacrificial electrode layer SM and the first and second upper electrode layers TE1 and TE2 may both include TiN. A thickness T6 of the sacrificial electrode layer SM may be greater than a thickness T1 of the first upper electrode layer TE1 and a thickness T2 of the second upper electrode layer TE2. For example, the thickness T6 may range from about 400 Å to about 600 Å.

Referring to FIGS. 6 and 7D, the first upper electrode layer TE1, the second upper electrode layer TE2, the second etch stop layer SL2, and the sacrificial electrode layer SM may be patterned (S140).

After forming mask patterns ML in the first region R1, the exposed sacrificial electrode layer SM, the etch stop layer SL2, the second upper electrode layer TE2, and the first upper electrode layer TE1 may be sequentially removed. The mask patterns ML may be removed after the patterning process. Alternatively, the mask patterns ML may be removed after the operation which will be described with reference to FIG. 7E.

In this operation, the second region R2 may be in an entirely opened state, and all of the exposed sacrificial electrode layer SM, the etch stop layer SL2, and the second upper electrode layer TE2 may be removed, while a portion of the first etch stop layer SL1 and the first upper electrode layer TE1 may remain, and the first etch stop layer SL1 may be exposed. Due to the first etch stop layer SL1 remaining only in the second region R2, the first upper electrode layer TE1 may not be removed in the second region R2. In this operation, the first etch stop layer SL1 may be partially removed in the second region R2 to have a reduced thickness T4′.

Referring to FIGS. 6 and 7E, the lower electrode layer BE and the magnetic tunnel junction structure layer MTJ may be patterned with an ion beam etch process to form preliminary cell structures CSp (S150).

The patterning process may be performed, for example, by a dry etching process, such as an ion beam etch process. By this, the preliminary cell structures CSp each including the lower electrode layer BE, the magnetic tunnel junction structure layer MTJ, the first upper electrode layer TE1, the second upper electrode layer TE2, the second etch stop layer SL2, and the sacrificial electrode layer SM, that are patterned, may be formed. The preliminary cell structures CSp may be formed by two patterning processes, as described above with reference to FIGS. 7D and 7E.

Between the preliminary cell structures CSp, the lower layer 196_1 of the third interlayer insulating layer 196 may be partially recessed. In this operation, the sacrificial electrode layer SM may be partially removed from the first region R1 to have a reduced thickness T6′. In the second region R2, the first etch stop layer SL1, the first upper electrode layer TE1, the magnetic tunnel junction structure layer MT, and the lower electrode layer BE may be sequentially removed to expose the lower layer 196_1.

Referring to FIGS. 6, 7F and 7G, spacer layer 170p may be formed, and then spacers 170 may be formed (S160).

The spacer layer 170p may cover upper surfaces and side surfaces of the preliminary cell structures CSp, and may extend onto an upper surface of the lower layer 196_1 of the third interlayer insulating layer 196. The spacer layer 170p may be formed by being deposited in-situ after the ion beam etch process. The spacer layer 170p may include an insulating material, for example, the same material as the second etch stop layer SL2. The spacer layer 170p may include, for example, SiN.

Next, as illustrated in FIG. 7G, the spacer layer 170p may be partially removed to form the spacers 170. In this operation, the spacer layer 170p may be removed by a process having a high selectivity with respect to a material forming the sacrificial electrode layer SM. Horizontally formed regions of the spacer layer 170p may be removed, and the spacers 170 formed thereby may be arranged only on the side surfaces of the preliminary cell structures CSp. The spacers 170 may be spaced apart from each other between the preliminary cell structures CSp, and thus the lower layer 196_1 of the third interlayer insulating layer 196 may be exposed. In the second region R2, the spacer layer 170p may be completely removed.

Referring to FIGS. 6 and 7H, the sacrificial electrode layers SM may be removed (S170).

The sacrificial electrode layers SM may be removed from an exposed upper surface by a wet cleaning process. The cleaning process may be performed using a wet cleaning agent, such as an EKC solution. The EKC solution is a product name of a wet cleaning agent for removing photoresist. During the cleaning process, a metal material which was redeposited on the lower layer 196_1 of the exposed third interlayer insulating layer 196 may also be removed together. The redeposited metal material may be a portion of a material forming at least one of the sacrificial electrode layer SM, the second upper electrode layer TE2, or the first upper electrode layer TE1 redeposited on the lower layer 196_1 during the ion beam etch process described above with reference to FIG. 7E. The redeposited metal material may be, for example, Ti and/or TiN. When the redeposited metal material is removed by a separate etch process, the lower layer 196_1 may be excessively recessed, but when it is removed by a wet cleaning process as in the present implementation, the lower layer 196_1 may be prevented from being excessively recessed between the preliminary cell structures CSp.

During the cleaning process, side surfaces of the lower electrode layer BE, the magnetic tunnel junction structure layer MTJ, the first upper electrode layer TE1, and the second upper electrode layer TE2 may be covered by the spacers 170 and an upper surface of the second upper electrode layer TE2 at the top thereof may be covered by the second etch stop layer SL2, and they may not be exposed. Accordingly, the cleaning process may be performed without damage or loss of the lower electrode layer BE, the magnetic tunnel junction structure layer MTJ, the first upper electrode layer TE1, and the second upper electrode layer TE2. In addition, even if an ashing process, etc. is performed later, the problem of the second upper electrode layer TE2 being oxidized during the process and causing a defect may be prevented.

Referring to FIGS. 6, 7I and 7J, an intermediate layer 196_2 of the third interlayer insulating layer 196 may be formed, and the second etch stop layer SL2 on the second upper electrode layers TE2 may be removed (S180).

The intermediate layer 196_2 of the third interlayer insulating layer 196 may fill regions where the sacrificial electrode layers SM are removed, and may be formed on the lower layer 196_1 of the third interlayer insulating layer 196. In the second region R2, third contact plugs 167 may be formed before or after forming of the intermediate layer 196_2 of the third interlayer insulating layer 196, and third interconnection lines 156 may be formed by partially removing the intermediate layer 196_2 of the third interlayer insulating layer 196 after forming the intermediate layer 196_2.

Next, as illustrated in FIG. 7J, a second barrier layer 197 and an upper layer 196_3 of the third interlayer insulating layer 196 may be formed, and trenches BT may be formed. The trenches BT may be formed by removing the exposed second etch stop layer SL2 after partially removing the third interlayer insulating layer 196 and the second barrier layer 197 in a region where the bit lines 180 (see FIG. 2) are arranged. When the second etch stop layer SL2 is removed, the spacers 170 may also be removed by a thickness of the second etch stop layer SL2, so that upper ends thereof may be lowered.

In this operation, as the second etch stop layer SL2 is removed, cell structures CS each including the lower electrode layer BE, the magnetic tunnel junction structure layer MTJ, the first upper electrode layer TE1, and the second upper electrode layer TE2 may be formed. The cell structures CS may be covered with the second etch stop layer SL2 and the sacrificial electrode layer SM during the patterning process described above with reference to FIG. 7E, so that no thickness dispersion may occur, and may only have a thickness dispersion during deposition. Therefore, compared to a comparative example in which the layer forming the cell structures CS is exposed during the patterning process described above with reference to FIG. 7E, thickness uniformity may be improved, and accordingly, the bit lines 180 formed in subsequent processes may be stably electrically connected.

Next, referring to FIG. 2 together, a semiconductor device 100 may be manufactured by forming the bit lines 180 by depositing a conductive material in the trenches BT.

By optimizing the processes of forming the second etch stop layer, the sacrificial electrode layer, and the spacer to improve a thickness dispersion of the magnetic tunnel junction MTJ structure and efficiently remove the redeposited metal without excessive recess of the interlayer insulating layer, a method for manufacturing a semiconductor device with improved electrical characteristics may be provided.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While example implementations have been shown and described above, it will be apparent to those skilled in the art that modifications and variations could be made without departing from the scope of the present disclosure as defined by the appended claims.

What is claimed is:

1. A method of manufacturing a semiconductor device, comprising:
forming an interlayer insulating layer and an interconnection structure on a substrate, the interconnection structure extending through at least a portion of the interlayer insulating layer, the substrate including a first region on which a plurality of memory cells are arranged and a second region on which a peripheral circuit is arranged;
sequentially forming a lower electrode layer, a magnetic tunnel junction structure layer, a first upper electrode layer, and a first etch stop layer on the interlayer insulating layer and the interconnection structure;
removing the first etch stop layer on the first region, and forming a second upper electrode layer on the first region and the second region;
sequentially forming a second etch stop layer and a sacrificial electrode layer on the first region and the second region;
forming a mask pattern on the first region, and patterning the first upper electrode layer, the second upper electrode layer, the second etch stop layer, and the sacrificial electrode layer with the mask pattern;
performing an ion beam etch process that patterns the lower electrode layer and the magnetic tunnel junction structure layer on the first region, and forming a plurality of preliminary cell structures, wherein each of the plurality of preliminary cell structures includes the lower electrode layer, the magnetic tunnel junction structure layer, the first upper electrode layer, the second upper electrode layer, the second etch stop layer, and the sacrificial electrode layer, which are sequentially stacked;
forming a spacer layer covering an upper surface and a plurality of side surfaces of each of the plurality of preliminary cell structures;
removing a portion of the spacer layer, thereby forming a plurality of spacers covering the respective plurality of side surfaces of the plurality of preliminary cell structures and spaced apart from each other between the plurality of preliminary cell structures;
removing the sacrificial electrode layer from each of the plurality of preliminary cell structures, thereby exposing the second etch stop layer;
removing the second etch stop layer from each of the plurality of preliminary cell structures, thereby exposing the second upper electrode layer; and
forming a bit line connected with each of the exposed second upper electrode layers.

2. The method of claim 1, wherein a thickness of the sacrificial electrode layer is greater than a thickness of the first upper electrode layer and a thickness of the second upper electrode layer.

3. The method of claim 1, wherein the sacrificial electrode layer is formed with a first thickness, and a portion of the sacrificial electrode layer is removed on the first region based on the ion beam etch process, so that the sacrificial electrode layer remains with a second thickness less than the first thickness.

4. The method of claim 3, wherein the second thickness ranges from 50 Å to 100 Å.

5. The method of claim 1, wherein the first upper electrode layer, the second upper electrode layer, and the sacrificial electrode layer include a same metal material.

6. The method of claim 1, wherein after removing the sacrificial electrode layer from each of the plurality of preliminary cell structures, each of the plurality of spacers protrudes onto the second etch stop layer.

7. The method of claim 6, wherein after removing the second etch stop layer, each of the plurality of spacers protrudes onto the second upper electrode layer.

8. The method of claim 1, wherein the sacrificial electrode layer is removed using a wet cleaning agent.

9. The method of claim 1, wherein during the ion beam etch process, a metal material from at least one of the first upper electrode layer, the second upper electrode layer, or the sacrificial electrode layer is redeposited on a surface of the interlayer insulating layer exposed between the plurality of preliminary cell structures, and
wherein in the removing the sacrificial electrode layer, the redeposited metal material is removed together with the sacrificial electrode layer.

10. The method of claim 1, wherein a plurality of lower ends of the plurality of spacers contact the interlayer insulating layer.

11. The method of claim 1, wherein a thickness of the second etch stop layer is less than a thickness of the first etch stop layer.

12. The method of claim 1, wherein the first etch stop layer is exposed on the second region based on the patterning the first upper electrode layer, the second upper electrode layer, the second etch stop layer, and the sacrificial electrode layer.

13. The method of claim 1, wherein the interlayer insulating layer is exposed on the second region based on the ion beam etch process.

14. A method of manufacturing a semiconductor device, comprising:
sequentially forming a lower electrode layer, a magnetic tunnel junction structure layer, a first upper electrode layer, and a first etch stop layer on a substrate;
removing the first etch stop layer in a region, and forming a second upper electrode layer;
sequentially forming a second etch stop layer and a sacrificial electrode layer on the second upper electrode layer;
patterning the lower electrode layer, the magnetic tunnel junction structure layer, the first upper electrode layer, the second upper electrode layer, the second etch stop layer, and the sacrificial electrode layer, thereby forming a plurality of preliminary cell structures spaced apart from each other;
forming a plurality of spacers covering a plurality of side surfaces of the plurality of preliminary cell structures and spaced apart from each other between the plurality of preliminary cell structures; and
sequentially removing the sacrificial electrode layer and the second etch stop layer from each of the plurality of preliminary cell structures.

15. The method of claim 14, wherein the removing the sacrificial electrode layer is performed in a state where the lower electrode layer, the magnetic tunnel junction structure layer, the first upper electrode layer, and the second upper electrode layer are not exposed.

16. The method of claim 15, wherein during the removing the sacrificial electrode layer, a plurality of side surfaces of the lower electrode layer, the magnetic tunnel junction structure layer, the first upper electrode layer, and the second upper electrode layer are covered with the plurality of spacers, respectively, and an upper surface of the second upper electrode layer is covered with the second etch stop layer.

17. The method of claim 14, wherein a thickness of the sacrificial electrode layer is greater than a thickness of the first upper electrode layer and a thickness of the second upper electrode layer.

18. The method of claim 14, wherein forming the plurality of preliminary cell structures comprises an ion beam etch process for at least some layers of the lower electrode layer, the magnetic tunnel junction structure layer, the first upper electrode layer, the second upper electrode layer, the second etch stop layer, and the sacrificial electrode layer.

19. A method of manufacturing a semiconductor device, comprising:
sequentially forming a lower electrode layer, a magnetic tunnel junction structure layer, and a first upper electrode layer on a substrate;
sequentially forming a second upper electrode layer, an etch stop layer, and a sacrificial electrode layer on the first upper electrode layer;
patterning the lower electrode layer, the magnetic tunnel junction structure layer, the first upper electrode layer, the second upper electrode layer, the etch stop layer, and the sacrificial electrode layer, thereby forming a plurality of preliminary cell structures spaced apart from each other;
forming a plurality of spacers covering a plurality of side surfaces of the plurality of preliminary cell structures and spaced apart from each other between the plurality of preliminary cell structures; and
removing the sacrificial electrode layer and the etch stop layer from each of the plurality of preliminary cell structures,
wherein a plurality of upper ends of the plurality of spacers are positioned on a level higher than an upper surface of the second upper electrode layer, and a plurality of lower ends of the plurality of spacers are positioned on a level lower than a lower surface of the lower electrode layer.

20. The method of claim 19, wherein the sacrificial electrode layer is selectively removed with respect to the plurality of spacers and the etch stop layer.
